(19) United States
(12) Patent Application Publication
(10) Pub. No.: US 2024/0136182 A1
(43) Pub. Date: Apr. 25, 2024

(54) Method of Fabricating Thin, Crystalline Silicon Film and Thin Film Transistors

(71) Applicant: Ramesh Kumar Harjivan Kakkad, New Taipei City (TW)

(72) Inventor: Ramesh Kumar Harjivan Kakkad, New Taipei City (TW)

(21) Appl. No.: 18/492,412

(22) Filed: Oct. 22, 2023

Related U.S. Application Data
(60) Provisional application No. 63/418,250, filed on Oct. 21, 2022.

(51) Int. Cl. H01L 21/02; H01L 21/265; H01L 29/66

(52) U.S. Cl. CPC H01L 21/02672; H01L 21/26513; H01L 29/66757; H01L 29/66765

(57) ABSTRACT

A method of forming a silicon film includes forming an amorphous, intrinsic, silicon layer on a substrate, forming a nickel pattern on the silicon layer, forming a first doped silicon region by doping phosphorus into a region of the silicon layer, and annealing to crystallize the silicon layer, the crystallization propagating by nickel induced lateral crystal growth starting from a portion of the silicon layer directly adjacent the nickel pattern on a first side of the first doped silicon region, propagating through the first doped silicon region to a second side of the first doped silicon region, and subsequently propagating to crystallize regions of the silicon layer to the second side of the first doped silicon region, the crystallization propagation through the first doped silicon region resulting in reduced nickel concentration, thereby forming a reduced nickel-concentration crystallized silicon layer to the second side of the first doped silicon region.

This application claims an invention disclosed in U.S. Provisional Application No. 63/418,250, filed Oct. 21, 2022, entitled “Method of Fabricating Thin Film Crystalline Silicon and Thin Film Transistors”. The benefit under 35 USC § 119(e) of the United States provisional application is hereby claimed, and the aforementioned applications are hereby incorporated by reference.

### BACKGROUND OF THE INVENTION

### Field of Disclosure

The present invention relates to a method of fabricating polysilicon film as well as devices incorporating such polysilicon film.

### Description of the Related Art

Polycrystalline silicon (polysilicon or poly Si) thin film transistors (TFT) are used in AMOLED displays as well as high-resolution LCD display applications. In the poly Si TFTs, a polycrystalline silicon layer is used as an active layer of the devices. Currently, in the industry, the polycrystalline silicon active layer of a TFT is fabricated by excimer laser annealing (ELA) of amorphous silicon (a-Si) thin film deposited on a large-area substrate such as glass. In an ELA process, a long, narrow laser beam is scanned over an amorphous silicon film to raise its temperature to crystallize it by a “melt and regrowth” process. The resulting crystalline silicon is called polycrystalline silicon (as it contains silicon crystals with several crystallographic orientations).

Even though the ELA process is widely used to fabricate polycrystalline silicon films for TFT devices, there are certain issues associated with the ELA approach. The ELA process is very expensive to operate and maintain. Further, when AMOLED displays are fabricated using TFTs incorporating ELA poly Si films, defects occur on the displayed images called ‘ELA scan mura”. These “scan mura” appear as a result of laser scanning during the crystallization process. A difference in crystalline quality of silicon at boundaries between successive laser scans leads to different TFT characteristics at the scan boundaries, resulting in the appearance of scan lines on the displayed images.

In order to reduce the appearance of scan-mura, complicated pixel circuits are used employing multiple TFTs and capacitors (such as 7 TFTs and 2 capacitors) at each sub-pixel of display to compensate for the difference in TFT characteristics. These additional devices crowd the pixel areas and thus limit the display resolution. Also, the additional devices affect the device yield, since the probability of defects occurring in the display increases with an increase in the number of devices.

Solid phase crystallization (SPC) is a simpler, less expensive method to crystallize amorphous silicon films formed on large area substrate. In SPC, silicon film is not melted during the crystallization. In conventional SPC, an amorphous silicon film deposited on a substrate is thermally heated (for example, in a furnace) at around 700 degrees Celsius for several minutes to cause crystallization of the silicon film. In this method, the entire film is crystallized simultaneously and there is no scanning. Thus, there are no scan-mura on the displayed images, and simpler pixel circuits (e.g., two transistors and one capacitor) can be used at each sub-pixel of AMOLED displays. This SPC would allow for higher resolution displays and would improve production yield.

Although the SPC method is relatively simple and inexpensive, and the image uniformity is better (no scan-mura), the performance of TFTs fabricated using SPC poly Si films is not adequate in terms of TFT sub-threshold swing and threshold voltages required for display applications. There are many intra-grain defects (defects within a crystal) and grain boundary defects (defects between adjacent crystals due to difference in crystal orientation) in SPC poly Si films, and these defects trap charge carriers and thus limit the TFT device performance. Even though both grain-boundary defects and intra-grain defects are found in thermally annealed (SPC) polysilicon films, the intra-grain defects seem to dominate the overall defect concentration. The presence of intra-grain defects is known to reduce an effective defect-free area down to 30 nm even though polysilicon grain size as determined by locations of grain-boundaries is in the range of 500 nm to 1 micrometer for an a-Si film crystallized in the practical temperature range of 600-700° C. These defects, especially the intra-grain defects lead to inadequate TFT device performance.

Another way to cause crystallization is by a process called metal-induced crystallization, where a metal, such as nickel or palladium acts as a catalyst for crystallization of amorphous silicon, which lowers the crystallization temperature by as much as 200-300 degrees C. Traditionally, in a metal-induced crystallization process, a thin layer of nickel or palladium is placed over and in contact with the entire a-Si film area to be crystallized. Incorporation of nickel or palladium into crystallizing silicon, however, negatively affects device performance. Alternatively, nickel has been placed discontinuously (in a pattern form) over an a-Si film, but upon annealing in this method, silicon crystals grow laterally in the amorphous silicon film from where the Ni patterns are in contact with the silicon film to where there is no nickel. This nickel induced lateral crystal growth in the silicon can proceed several micrometers from the nickel patterns in a reasonable time at temperature below 500° C. or even at 400° C.

The mechanism by which nickel induced lateral crystallization takes place is as follows. The Ni forms nickel silicide by reacting with amorphous silicon under the patterns. The nickel silicide further reacts with any adjacent amorphous silicon, and in doing so, gives up silicon from previously formed nickel silicide. The dissociated silicon from the nickel silicide is in crystalline silicon. This reaction of consuming amorphous silicon and leaving behind crystalline silicon proceeds since the reaction is energetically favorable. That is, overall reaction of amorphous silicon to crystalline silicon transition lowers the system energy. Thus, a nickel front (in the form of nickel silicide) keeps moving laterally as long as there is amorphous silicon available and as long as there is adequate temperature to overcome activation energy for the reaction to proceed. The nickel incorporation in the lateral crystal growth regions, where there is no nickel pattern, is much lower than the regions under the nickel pattern. This technique is referred to as metal induced lateral crystallization, or the technique can be simply referred to as metal-induced-crystallization. TFTs have been fabricated by placing nickel patterns located several micrometers apart over an amorphous silicon film, annealing to cause lateral crystallization of the a-Si between the patterns, and forming active layer of TFTs within the laterally crystallized silicon. The electric current in such a TFT device flows in the direction of the lateral crystal growth, and thus current flow would generally encounter one grain boundary perpendicular to its flow direction. This results in improved device performance in terms of higher on-current, lower threshold voltage and higher switching speed compared to a device formed using the SPC process.

Although nickel incorporation in the laterally crystallized silicon is lower compared to nickel incorporation in silicon directly under the nickel, there is still some nickel present in the lateral growth area. This presence of nickel in laterally crystallized silicon can affect random TFTs formed using this technique, and can be seen on a displayed image as a defect (e.g. a bright pixel). Thus TFTs fabricated by using polycrystalline silicon film formed by metal induced lateral crystallization are currently not used in display production, in spite of having an advantage of lower crystallization temperature and adequate TFT device performance in terms of threshold voltage and sub-threshold swing.

### SUMMARY OF THE INVENTION

Methods are provided to form crystalline silicon (polycrystalline silicon) thin film with reduced nickel incorporation during a nickel induced lateral crystallization process of amorphous silicon and to incorporate the crystalline silicon film in a TFT device. In the methods, phosphorus doped regions can be formed in the precursor amorphous silicon film or layer between nickel patterns and silicon regions to be used for device applications. The phosphorus doped regions getter nickel during the nickel induced lateral crystallization process and reduce nickel concentration in the subsequently crystallized silicon, which can be used for device fabrication.

In an embodiment, a method of forming a silicon film includes forming an intrinsic, amorphous silicon layer on a substrate, forming a nickel pattern on the amorphous silicon layer, forming a first doped silicon region by doping phosphorous into a selected region of the amorphous silicon layer, and annealing to cause crystallization of the silicon layer. The crystallization propagates by nickel induced lateral crystal growth starting from a portion of the silicon layer located directly adjacent the nickel pattern on a first side of the first doped silicon region, propagating through the first doped silicon region to a second side of the first doped silicon region, and subsequently propagating to crystallize regions of the silicon layer to the second side of the first doped silicon region, the crystallization propagation through the first doped silicon region resulting in reduction in nickel concentration, thereby forming a reduced nickel-concentration crystallized silicon layer to the second side of the first doped silicon region.

In another embodiment, a method of forming a TFT device includes forming an intrinsic, amorphous silicon layer on a substrate, forming a first nickel pattern and a second nickel pattern on the amorphous silicon layer, forming first doped silicon regions by doping phosphorus into selected regions of the amorphous silicon layer between the first nickel pattern and the second nickel pattern, and annealing to cause crystallization of the amorphous silicon layer. The crystallization propagates by nickel induced lateral crystal growth starting from the silicon layer located under the nickel patterns, propagating through the first doped silicon regions, and subsequently propagating to crystallize regions of the silicon layer between the first doped silicon regions, the crystallization propagation through the first doped silicon regions resulting in reduction in nickel concentration, thereby forming a reduced nickel-concentration crystallized silicon layer between the first doped silicon regions.

### BRIEF DESCRIPTION OF THE DRAWINGS

FIG. 1A is a schematic diagram showing a known technique of forming a polycrystalline silicon film using a metal catalyst;

FIG. 1B is a schematic diagram showing a known technique of forming a polycrystalline silicon thin film transistor using a metal catalyst;

FIG. 2A is a schematic diagram showing a technique of forming a polycrystalline silicon film using a metal catalyst, according to an embodiment of the invention;

FIG. 2B is a schematic diagram showing a technique of forming a top gate polycrystalline silicon thin film transistor using a metal catalyst, according to an embodiment of the invention.

FIG. 2C is a schematic diagram showing a technique of forming a polycrystalline silicon film using a metal catalyst with the metal patterns partially overlapping phosphorus doped silicon regions, according to an embodiment of the invention.

FIG. 3 is a schematic diagram showing a technique of forming a bottom gate polycrystalline silicon thin film transistor using a metal catalyst, according to an embodiment of the invention.

### DETAILED DESCRIPTION OF THE INVENTION

The terminology used herein is for the purpose of describing particular example embodiments only and is not intended to be limiting. As used herein, the singular forms “a”, “an”, and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

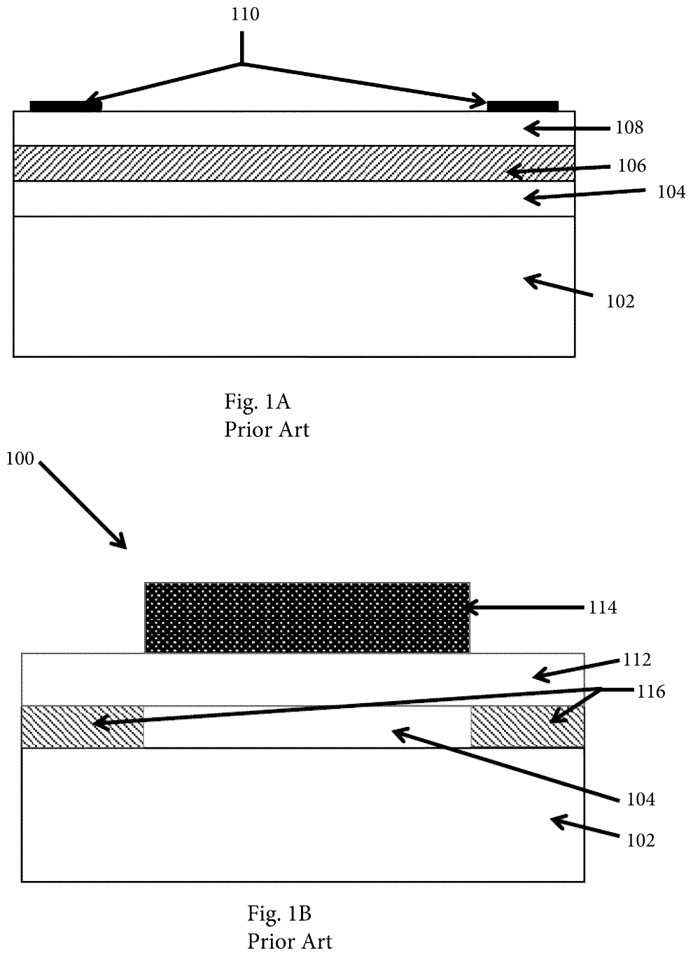

In order to reduce nickel concentration in silicon during metal induced lateral crystallization of amorphous silicon, a method was disclosed in U.S. patent application Ser. No. 18/466,644. A phosphorus doped silicon layer was used to separate nickel patterns from a silicon layer used for device fabrication. This method is illustrated in the example of FIG. 1A and FIG. 1B. In FIG. 1A, a phosphorus doped silicon layer 106 (amorphous when formed) separates a first intrinsic silicon layer 104 (amorphous when formed) from nickel patterns 110. The first intrinsic silicon layer 104 is to be used for device fabrication. In the example of FIG. 1A, a second intrinsic silicon layer 108, which is amorphous, is between the nickel patterns 110 and the phosphorus doped silicon layer 106. During annealing, nickel from the nickel patterns 110 moves downwards into the second intrinsic silicon layer 108, passing through the phosphorus doped silicon layer 106 and into the first intrinsic silicon layer 104, where the nickel laterally crystallizes the first intrinsic silicon layer 104. Nickel concentration in the first intrinsic silicon layer 104 is reduced as phosphorus in the phosphorus doped silicon layer 106 getters nickel. The lateral crystallization of the first intrinsic silicon layer 104 proceeds as discussed in the “Background of the Invention” section hereinabove, but with a lower nickel concentration because of gettering of nickel in the phosphorus doped silicon layer 106.

There is another crystallization pathway in this case. First, the second intrinsic silicon layer 108 is laterally crystallized starting from the nickel patterns 110, followed by vertical crystal growth from the second intrinsic silicon layer 108 to the phosphorus doped silicon layer 106, and continuing to the first intrinsic silicon layer 104. The crystal orientation in the layers 106, 104 is the same as that in the second intrinsic silicon layer 108. In this case also, the phosphorus doped silicon 106 getters nickel and thus lowers the concentration of nickel in the first intrinsic silicon layer 104. Since vertical crystal growth distances are much smaller compared to lateral growth distances, once the second intrinsic silicon layer 108 has been crystallized laterally, vertical growth from there to the first intrinsic silicon layer 104 occurs over a significantly shorter time, even if the is very low or no nickel reaching the first intrinsic silicon layer 104.

A TFT device 100 shown in FIG. 1B can be formed using the crystallized first intrinsic silicon layer 104 by removing the second intrinsic silicon layer 108 and the phosphorus doped silicon layer 106, forming source-drain regions 116 in the crystallized first intrinsic silicon layer 104 by doping, forming a gate insulator layer 112, and forming a gate electrode 114.

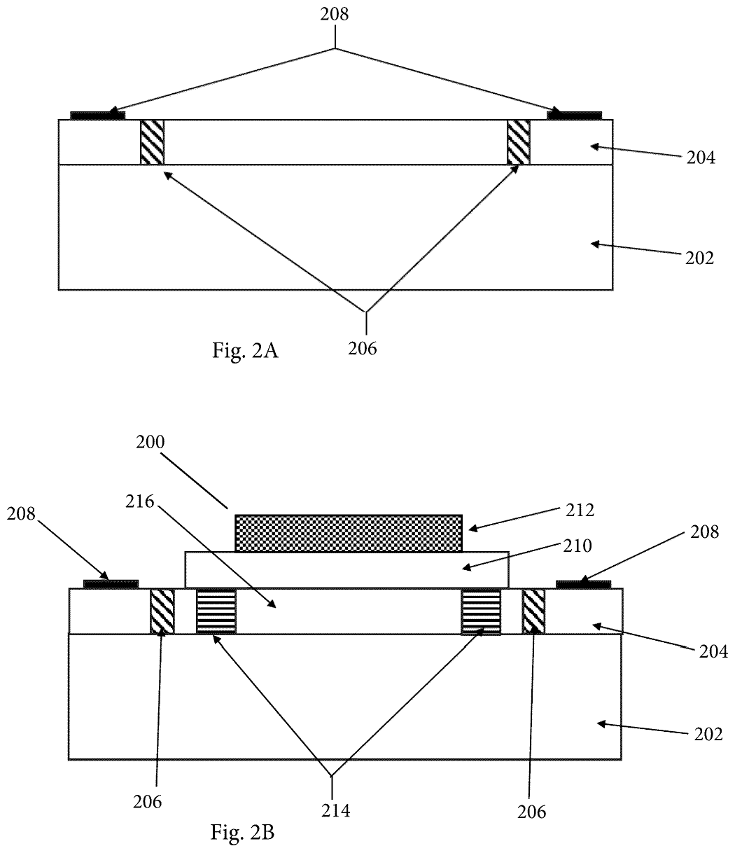

In the current invention, we disclose a simpler process to reduce the nickel incorporation in the device channel during nickel induced lateral crystallization of silicon. The following example, as shown in FIG. 2A illustrates such a process. On a substrate 202, a first silicon layer 204 is formed. The first silicon layer 204 is amorphous and intrinsic when formed. It can be beneficial for the first silicon layer 204 to have a thickness in the range of 200-1000 angstroms, depending upon device application. Selected regions of the first silicon layer 204 would be used to form a source, drain, and channel of a TFT device. The first silicon layer 204 can be doped at low doping concentration in the range of 10¹⁸ cm⁻³ or lower to adjust the threshold voltage of a device. Silicon doped at these low concentrations can be considered to be intrinsic silicon.

Certain selected regions of the first silicon layer 204, outside of an area intended to be a channel region 216 (see FIG. 2B), are doped with phosphorus, creating first phosphorus doped silicon regions 206, between which a channel of a TFT can be formed. The phosphorus doping can be carried out by implanting phosphorus into the silicon in the selected regions. It can be beneficial to dope phosphorous in these regions at a concentration of 10²⁰ cm⁻³ or higher. In one example, phosphorus is doped at a concentration of 5×10²⁰ cm⁻³ for the regions 206.

Outside of the phosphorus doped silicon regions 206, nickel patterns 208 are formed on the silicon layer 204 as shown. Thus, phosphorus doped silicon regions 206 are located between the channel region and the nickel patterns 208. Subsequently, annealing of the silicon layer 204 is performed at elevated temperature to crystallize it. Upon annealing, silicon in the first silicon layer 204 located under the nickel patterns 208 reacts with nickel to form nickel silicide and a nickel silicide front that moves laterally in correlation with lateral crystallization. The nickel silicide reacts with adjacent amorphous silicon in the first silicon layer 204, and in doing so, gives up silicon from previously formed nickel silicide. The dissociated silicon from the nickel silicide is in crystalline silicon form. Thus, the nickel silicide front moves laterally as the nickel silicide keeps consuming amorphous silicon and leaving behind crystalline silicon.

The nickel silicide front moves laterally in either direction to cause crystallization of the first silicon layer 204. The nickel silicide front moves laterally through the phosphorus doped silicon regions 206 and continues to crystallize the first silicon layer 204 located between the phosphorus doped regions 206. Because phosphorus acts as a gettering agent for nickel, the nickel concentration in the crystallizing silicon reduces as the nickel silicide front passes through the phosphorus doped silicon regions 206, which results in lower nickel incorporation in the crystallized first silicon layer 204 between phosphorus doped regions 206. The elevated temperature is maintained until the lateral crystallization is complete, for example, when two nickel silicide fronts propagating from opposite directions meet in the first silicon layer 204 at a location about equidistant between the phosphorous doped regions 206. At the meeting point, a grain boundary perpendicular to the crystallization direction forms. A portion of the intrinsic crystallized first silicon layer 204 in the region between the phosphorus doped silicon regions 206 would be used to form the channel of a TFT device, as stated hereinabove.

FIG. 2B shows a formation of a TFT device 200 using the silicon layer crystallized by this process. A gate insulator layer 210 and a gate electrode 212 are formed on the first silicon layer 204. Source-drain regions 214 are formed by doping regions of the first silicon layer 204 with a doping type consistent with the desired device type. For example, p-type doping (such as by using boron) is applied for p-type TFTs and n-type doping (such as by using phosphorus) is applied for n-type TFTs. The portion of the first silicon layer 204 located between source-drain regions 214 is the channel region 216 of the TFT device 200. Generally, for source and drains regions, high doping concentrations, of the order of 10²⁰ cm⁻³ or higher are needed. Such doping levels are denoted as N+ doping for n-type dopants and P+ for p-type dopants. For n-type TFTs, in source-drain regions, generally lightly doped regions (referred to as N-doping or N− regions) are formed covering the entire lengths between N+ doping regions and channel on either side of the channel. The presence of N− doping regions between N+ doping regions and channel lead reduces electric field, and thus reduces leakage current during device operation. Thus, a two-step doping process is needed to form source-drain regions for an n-type TFT—one step to form N+ portions of source-drain regions, and one step to form N− portions of source-drain regions. For n-type TFTs, it is also possible to use phosphorus doped silicon regions 206 as N+ portions of source-drain instead of forming source-drain regions 214, while the N− portions can be formed by lightly doping spaces between the channel 216 and the phosphorus doped silicon regions 206 (on both sides of the channel 216). In this way, the number of doping steps is reduced in the case of forming n-type TFTs. In the case of forming p-type TFTs, boron doping for source and drain regions 214 can also be carried out before the crystallization annealing.

As discussed hereinabove, a grain boundary is formed in the first silicon layer 204 in the direction perpendicular to the crystallization direction, and thus the grain boundary would be perpendicular to current flow and would be located in the channel 216, as the channel 216 is generally formed in the middle. If no grain boundary is desired in the middle of a device, the nickel pattern 208 and the phosphorus doped region 206 (or only the nickel pattern 208) can be formed only on one side of the desired channel area of a device. Doing so, however, will increase the crystallization time, as a longer distance needs to be covered during the lateral crystallization. Alternatively, the channel 216 is so placed as to avoid having the grain boundary within it. The length of the phosphorus doped silicon regions 206 can affect the nickel concentration after the nickel silicide front propagates through them and thus also can affect subsequent crystallization speed. If the phosphorus doped regions 206 are too long, nickel incorporation can be significantly reduced, which could lower crystallization speed after the nickel silicide front passes through the phosphorus doped silicon regions 206 and thus can increase crystallization time. An appropriate length of one of the phosphorus doped regions 206 can be 0.2-3.0 micrometers, but depending upon design rule capability of the fabrication equipment, the length can be increased by one or two micrometers. The time required for crystallization is also affected by crystallization temperature, with higher temperature requiring less time, and desired temperature would be 500 degrees centigrade or lower. The nickel patterns 208 are spaced apart laterally from the phosphorus doped regions 206, but if needed, the nickel patterns 208 can each be formed at least partially on a respective one of the phosphorous doped regions 206, such that each of the nickel patterns 208 overlaps part of a respective one of the phosphorus doped regions 206, as shown in FIG. 2C. In the case of an overlap, a portion of each phosphorus doped region 206 disposed towards a channel side of each phosphorous doped region 206 can remain uncovered with nickel patterns 208. In other words, after forming the first nickel pattern and the second nickel pattern and forming the first doped silicon regions, a length of the silicon layer 204 spanning between the first doped silicon regions 206 is entirely between the nickel patterns 208, and the nickel patterns 208 are each on less than a full portion of a respective one of the first doped silicon regions 206. Keeping at least a portion of each of the phosphorous doped regions 206 uncovered in this way facilitates some length of the phosphorus doped region 206 between the channel 216 and the nickel patterns 208 remaining available to getter nickel.

The process described in this invention is different from the conventional nickel induced lateral crystallization process (described in the Description of the Related Art section above) by the fact that, in this invention, the phosphorus doped silicon region 206 is formed between the nickel patterns 208 and the channel region 216 before crystallization in order to reduce nickel incorporation in the channel during the crystallization. As mentioned hereinabove, substantial nickel incorporation in the channel region of polycrystalline silicon TFTs formed using the conventional nickel induced lateral crystallization process is the reason that the conventional nickel induced lateral crystallization process is not used in the AMOLED production.

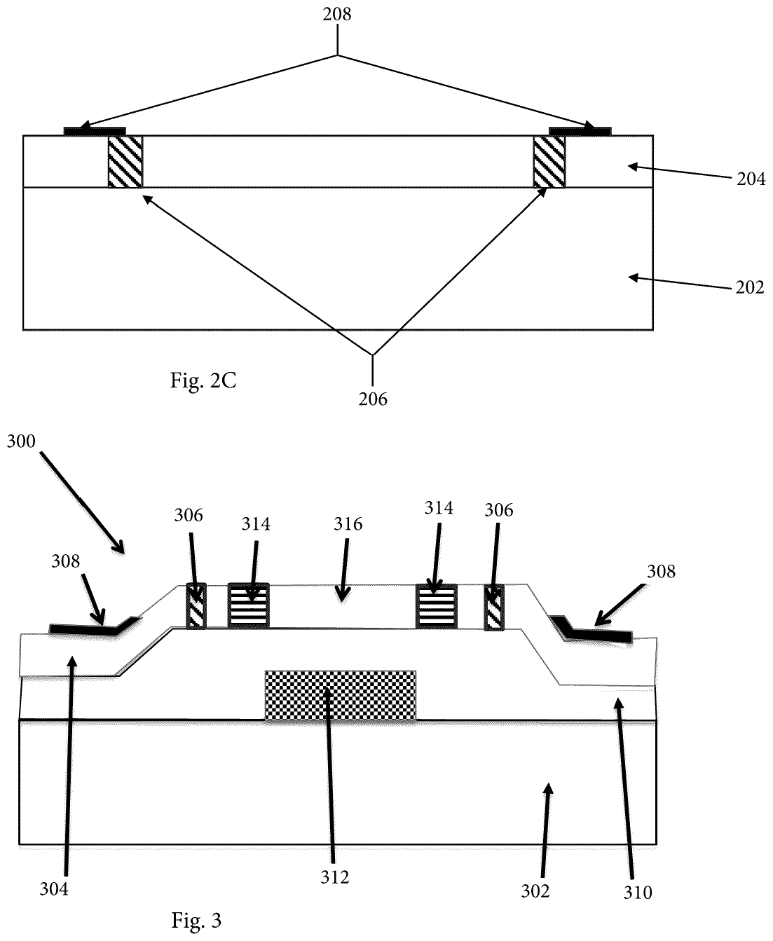

The TFT device 200 of FIG. 2B is a top gate TFT formed over the substrate 202. The same structure can be flipped over the substrate 202 and then called a bottom gate TFT 300, as shown in FIG. 3. In the bottom gate TFT case, the order of formation of the gate electrode 212, the gate insulator 210 and the first silicon layer 204 are reversed over the substrate 202. That is, first on a substrate 302, a gate electrode pattern 312 is formed, followed by formation of a gate insulator 310, followed by formation of a first silicon layer 304. The first silicon layer is intrinsic and amorphous at formation, and is subsequently crystallized in a manner similar to the method described hereinabove, that is, by forming phosphorus doped silicon regions 306 (for gettering of nickel) and nickel patterns 308, and annealing to cause nickel induced crystallization. As before, source and drain regions 314 are formed by additional doping(s), creating a channel 316.

The bottom gate structure is not preferred in polycrystalline silicon TFTs, as aligning the gate electrode 312 with the channel region 316 is difficult. In the top gate structure shown in FIG. 2B, the channel region 216 is automatically aligned with the gate electrode 212, when the gate electrode 212 is used as a channel mask during the implantation of a dopant into the first silicon layer 204 to create the source-source drain regions 214.

Compared to the nickel induced crystallization discussed with reference to FIG. 1A and FIG. 1B (and disclosed in U.S. patent application Ser. No. 18/466,644) where the nickel patterns are separated from an intrinsic silicon layer by a phosphorus doped silicon layer, the current approach advantageously has a simpler process and fewer process steps. For example, in the process of forming the device of FIG. 1A, extra layers have to be formed, including the phosphorus doped silicon layer 106 and the second intrinsic silicon layer 108, which need to be removed before forming the TFT device of FIG. 1B. The deposition and subsequent removal of such layers is not needed in the current approach.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A method of forming a TFT device, the method comprising:
forming a silicon layer on a substrate, the silicon layer being amorphous and intrinsic at formation;
forming a first nickel pattern and a second nickel pattern on the silicon layer, the silicon layer being amorphous;
forming first doped silicon regions by doping phosphorus into selected regions of the silicon layer between the first nickel pattern and the second nickel pattern, the silicon layer being amorphous;
annealing to cause crystallization of the amorphous silicon layer, wherein the crystallization propagates by nickel induced lateral crystal growth starting from the silicon layer located under the nickel patterns, propagating through the first doped silicon regions, and subsequently propagating to crystallize regions of the silicon layer between the first doped silicon regions, the crystallization propagation through the first doped silicon regions resulting in reduction in nickel concentration, thereby forming a reduced nickel-concentration crystallized silicon layer between the first doped silicon regions.

2. The method of forming a TFT device as recited in claim 1, the method further comprising:
forming second doped silicon regions in the silicon layer between the first doped silicon regions to form source-drain regions and a channel region between the first doped silicon regions, the source-drain regions disposed on either side of the channel region;
forming a gate insulator layer on the channel region; and
forming a gate electrode on the gate insulator layer.

3. The method of forming a TFT device as recited in claim 2, wherein the channel region is laterally spaced apart from the first nickel pattern by a first one of the first doped regions and from the second nickel pattern by a second one of the first doped regions.

4. The method of forming a TFT device as recited in claim 2, wherein the first doped silicon regions are laterally spaced apart from the channel region.

5. The method of forming a TFT device as recited in claim 2, wherein the nickel concentration in the channel region is lower than it would been without the presence of the first doped silicon regions between the channel and the nickel patterns.

6. The method of forming a TFT device as recited in claim 2, wherein the second doped silicon regions are p-type doped.

7. The method of forming a TFT device as recited in claim 2, wherein the second doped regions are n-type doped.

8. The method of forming a TFT device as recited in claim 1, further comprising:
forming a gate electrode on the substrate;
forming a gate insulator on the gate electrode;
forming second doped silicon regions in the silicon layer between the first doped silicon regions to form source-drain regions and a channel region between the first doped silicon regions, the source-drain regions disposed on either side of the channel region.

9. The method of forming a TFT device as recited in claim 1, wherein the phosphorus concentration in the first doped silicon regions is 10²⁰ cm⁻³ or higher.

10. The method of forming a TFT device as recited in claim 1, wherein the first doped silicon regions are formed by implantation of phosphorus into the silicon layer.

11. The method of forming a TFT device as recited in claim 1, wherein the thickness of the silicon layer is between 200-1000 angstroms.

12. The method of forming a TFT device as recited in claim 1, wherein the annealing temperature is 500 degrees Centigrade or lower.

13. The method of forming a TFT device as recited in claim 1, wherein the length of each of the first doped silicon regions is between 0.2 micrometers and 3.0 micrometers.

14. The method of forming a TFT device as recited in claim 1, wherein the length of each of the first doped silicon regions is between 0.2 micrometers and 5.0 micrometers.

15. The method of forming a TFT device as recited in claim 1, wherein, after forming the first nickel pattern and the second nickel pattern and forming the first doped silicon regions, the first nickel pattern and the second nickel pattern on the silicon layer are spaced apart laterally from the first doped silicon regions.

16. The method of forming a TFT device as recited in claim 1, wherein, after forming the first nickel pattern and the second nickel pattern and forming the first doped silicon regions, the first nickel pattern is at least partially on a first one of the first doped silicon regions, and the second nickel pattern is at least partially on a second one of the first doped silicon regions.

17. The method of forming a TFT device as recited in claim 1, wherein forming the first doped silicon regions includes forming a first one of the first doped silicon regions and a second one of the first doped silicon regions, the first one spaced from the second one by a length of the silicon layer, wherein, after forming the first nickel pattern and the second nickel pattern and forming the first doped silicon regions, the length of the silicon layer is entirely between the first nickel pattern and the second nickel pattern, the first nickel pattern is on less than a full portion of the first one of the first doped silicon regions, and the second nickel pattern is on less than a full portion of the second one of the first doped silicon regions.

18. A method of forming a silicon film, the method comprising:
forming a silicon layer on a substrate, the silicon layer being amorphous and intrinsic at formation;
forming a nickel pattern on the silicon layer, the silicon layer being amorphous;
forming a first doped silicon region by doping phosphorus into a selected region of the silicon layer, the silicon layer being amorphous;
annealing to cause crystallization of the silicon layer, wherein the crystallization propagates by nickel induced lateral crystal growth starting from a portion of the silicon layer located directly adjacent the nickel pattern on a first side of the first doped silicon region, propagating through the first doped silicon region to a second side of the first doped silicon region, and subsequently propagating to crystallize regions of the silicon layer to the second side of the first doped silicon region, the crystallization propagation through the first doped silicon region resulting in reduction in nickel concentration, thereby forming a reduced nickel-concentration crystallized silicon layer to the second side of the first doped silicon region.

19. The method of forming a silicon film as recited in claim 18, wherein the first doped silicon regions are formed by implantation of phosphorus into the silicon layer.

20. The method of forming a silicon film as recited in claim 18, wherein the nickel pattern on the silicon layer is spaced apart laterally from the first doped silicon region.
